(19) United States
(12) Patent Application Publication
(10) Pub. No.: US 2024/0212744 A1
(43) Pub. Date: Jun. 27, 2024

(54) MEMORY DEVICE TO PRECHARGE BITLINES PRIOR TO SENSING MEMORY CELLS

(71) Applicant: Micron Technology, Inc., Boise, ID (US)

(72) Inventors: Umberto di Vincenzo, Capriate San Gervasio (BG) (IT); Ferdinando Bedeschi, Biassono (MB) (IT)

(21) Appl. No.: 18/537,685

(22) Filed: Dec. 12, 2023

Related U.S. Application Data
(60) Provisional application No. 63/476,918, filed on Dec. 22, 2022.

(51) Int. Cl. G11C 11/4094; G11C 11/4096; G11C 11/4099

(52) U.S. Cl. CPC G11C 11/4094; G11C 11/4096; G11C 11/4099

(57) ABSTRACT

Systems, methods, and apparatus related to memory devices. In one approach, a memory device uses an architecture having a precharge transistor in parallel with a cascode transistor. The precharge transistor (e.g., a p-channel device) performs precharging of a bitline to a fixed constant voltage in preparation for sensing a memory cell. The cascode transistor (e.g., an n-channel device) is used to determine the voltage of the bitline during sensing and discharges a sensing node if the memory cell switches (e.g., snaps). The sensing node is coupled to an input of a detector that determines the logic state of the memory cell.

### RELATED APPLICATIONS

The present application claims priority to Prov. U.S. Pat. App. Ser. No. 63/476,918 filed Dec. 22, 2022, the entire disclosure of which application is hereby incorporated herein by reference.

### FIELD OF THE TECHNOLOGY

At least some embodiments disclosed herein relate to memory devices in general, and more particularly, but not limited to a memory device that precharges bitlines and/or other access lines prior to sensing a state of memory cells.

### BACKGROUND

Memory devices are widely used to store information in various electronic devices such as computers, wireless communication devices, cameras, digital displays, and the like. Information is stored by programming different states of a memory device. For example, binary devices have two states, often denoted by a logic “1” or a logic “0”. In other systems, more than two states may be stored. To access the stored information, a component of the electronic device may read, or sense, the stored state in the memory device. To store information, a component of the electronic device may write, or program, the state in the memory device.

Various types of memory devices exist, including magnetic hard disks, random access memory (RAM), read only memory (ROM), dynamic RAM (DRAM), synchronous dynamic RAM (SDRAM), ferroelectric RAM (FeRAM), magnetic RAM (MRAM), resistive RAM (RRAM), flash memory, phase change memory (PCM), and others. Memory devices may be volatile or non-volatile. Non-volatile memory cells may maintain their stored logic state for extended periods of time even in the absence of an external power source. Volatile memory cells may lose their stored state over time unless they are periodically refreshed by an external power source.

A storage device is an example of a memory device. Typical computer storage devices have controllers that receive data access requests from host computers and perform programmed computing tasks to implement the requests in ways that may be specific to the media and structure configured in the storage devices. In one example, a memory controller manages data stored in memory and communicates with a computer device. In some examples, memory controllers are used in solid state drives for use in mobile devices or laptops, or media used in digital cameras.

Firmware can be used to operate a memory controller for a particular storage device. In one example, when a computer system or device reads data from or writes data to a memory device, it communicates with the memory controller.

Memory devices often store data in memory cells. In some cases, memory cells exhibit non-uniform, variable electrical characteristics that may originate from various factors including statistical process variations, cycling events (e.g., read or write operations on the memory cells), or a drift (e.g., a change in resistance of a chalcogenide alloy), among others.

In one example, reading a set of data (e.g., a codeword, a page) is carried out by determining a read voltage (e.g., an estimated median of threshold voltages) of memory cells that store the set of data. In some cases, a memory device may include an array of PCM cells arranged in a 3D architecture, such as a cross-point architecture to store the set of data. PCM cells in a cross-point architecture may represent a first logic state (e.g., a logic 1, a SET state) associated with a first set of threshold voltages, or a second logic state (e.g., a logic 0, a RESET state) associated with a second set of threshold voltages. In some cases, data may be stored using encoding (e.g., error correction coding (ECC)) to recover data from errors in the data stored in the memory cells.

For resistance variable memory cells (e.g., PCM cells), one of a number of states (e.g., resistance states) can be set. For example, a single level cell (SLC) may be programmed to one of two states (e.g., logic 1 or 0), which can depend on whether the cell is programmed to a resistance above or below a particular level. As an additional example, various resistance variable memory cells can be programmed to one of multiple different states corresponding to multiple data states, e.g., 10, 01, 00, 11, 111, 101, 100, 1010, 1111, 0101, 0001, etc. Such cells may be referred to as multi state cells, multi-digit cells, and/or multi-level cells (MLCs).

The state of a resistance variable memory cell can be determined (e.g., read) by sensing current through the cell responsive to an applied interrogation voltage. The sensed current, which varies based on the resistance of the cell, can indicate the state of the cell (e.g., the binary data stored by the cell). The resistance of a programmed resistance variable memory cell can drift (e.g., shift) over time. Resistance drift can result in erroneous sensing of a resistance variable memory cell (e.g., a determination that the cell is in a state other than that to which it was programmed, among other issues).

A PCM cell, for example, may be programmed to a reset state (amorphous state) or a set state (crystalline state). A reset pulse (e.g., a pulse used to program a cell to a reset state) can include a relatively high current pulse applied to the cell for a relatively short period of time such that the phase change material of the cell melts and rapidly cools, resulting in a relatively small amount of crystallization. Conversely, a set pulse (e.g., a pulse used to program a cell to a set state) can include a relatively lower current pulse applied to the cell for a relatively longer time interval and with a slower quenching speed, which results in an increased crystallization of the phase change material.

A programming signal can be applied to a selected memory cell to program the cell to a target state. A read signal can be applied to a selected memory cell to read the cell (e.g., to determine the state of the cell). The programming signal and the read signal can be current and/or voltage pulses, for example.

### BRIEF DESCRIPTION OF THE DRAWINGS

The embodiments are illustrated by way of example and not limitation in the figures of the accompanying drawings in which like references indicate similar elements.

FIG. 1 shows a memory device that first precharges bitlines in a precharging phase in preparation for sensing memory cells in a memory array, and then turns off the precharging during sensing of the memory cells, in accordance with some embodiments.

FIG. 2 shows an exemplary current-voltage (I-V) curve for a memory cell, in accordance with some embodiments.

FIG. 3 shows circuitry having parallel precharging and sensing paths for detecting a state of a memory cell, in accordance with some embodiments.

FIG. 4 shows exemplary voltage waveforms for the circuitry of FIG. 3, in accordance with some embodiments.

FIG. 5 shows bias circuitry coupled to a fixed voltage source for precharging a bitline, and sensing circuitry including a cascode transistor (e.g., N1) having a gate coupled to the fixed voltage source, in accordance with some embodiments.

FIG. 6 shows an exemplary three-dimensional memory array structure including memory cells that are sensed by a detector, in accordance with some embodiments.

FIG. 7 shows a method for precharging a bitline prior to sensing a memory cell, in accordance with some embodiments.

### DETAILED DESCRIPTION

The following disclosure describes various embodiments for a memory device that senses memory cells in a memory array by using a detector. The memory device first precharges bitlines in a precharging phase in preparation for sensing the memory cells. After the bitlines are precharged, the memory device turns off the precharging. Then, the detector senses a logic state of the memory cells.

The memory device may, for example, store data used by a host device (e.g., a computing device of an autonomous vehicle, or another computing device that accesses data stored in the memory device). In one example, the memory device is a solid-state drive mounted in an electric vehicle.

In existing memory devices, there is a need to read memory cells using a sense amplifier to detect switching of the cells. In one example, the memory cells are phase change memory cells (e.g., chalcogenide cells) which exhibit a snapback behavior when switching. There are several different types of detectors that may be used to sense a state of a cell by sensing a voltage on a bitline. For example, the detector may use a cascoded-based architecture, a sense amplifier-based architecture, or an inverter-based architecture.

In one example of a cascoded-based architecture, a cascode transistor is used in series with a transistor that provides a supply voltage for precharging memory cells. The presence of the cascode transistor (and sometimes other transistors) in series with the supply voltage used for the precharging causes the need for a significant time to precharge the memory cells. Also, the series cascode transistor requires a higher supply voltage due to the voltage drop across the cascode transistor. In part, the length of the precharge is long because of the use of an n-channel cascode transistor with a positive supply voltage. This results in an exponential precharge bitline voltage waveform with a long tail.

Another problem is that a reference current is used to sense each memory cell, but leakage currents of other cells in the memory array are highly variable and affect the sensing. It is difficult to select an appropriate reference current that is greater than this leakage due to the random nature of the leakage (e.g., variations at different locations and/or for different patterns of cells in the memory array). Thus, in practice, the reference current must be set higher than is desirable. This causes excess power consumption. The leakage current may also cause false detections of memory cell switching by prematurely pulling down the voltage on an input node for a detector of the sensing circuitry.

In addition, there is the problem that the threshold voltage of the cascode transistor can vary significantly from one sense amplifier to another. This causes a variation in the voltage reached by the bitline even if the gate voltage on the cascode transistor is constant for all of the sense amplifiers.

To address the above and other technical problems, a memory device uses an architecture having a precharge transistor in parallel with a cascode transistor. The precharge transistor (e.g., a p-channel MOS device) performs precharging of a bitline to prepare for sensing a memory cell. The cascode transistor is used to determine the voltage of the bitline during sensing.

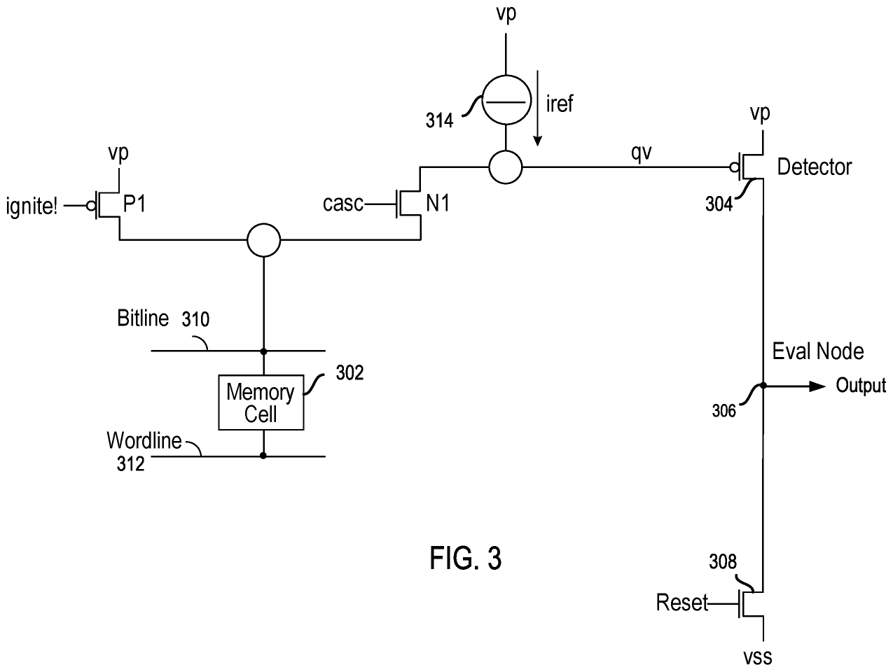

An advantage of using the precharge transistor is that the bitline can be raised to a fixed value of the supply voltage (e.g., vp). The precharge transistor (e.g., P1 of FIG. 3) provides a precharge current to increase the bitline voltage. This avoids passing the precharge current through the cascode transistor as in the existing devices above.

This parallel precharging structure can provide another advantage. For example, the supply voltage can be provided by a voltage regulator. The supply voltage is a constant fixed value for all sense amplifiers in a memory device. Thus, the cascode device does not determine the initial voltage of the bitline when starting a sensing operation.

Also, the precharge is faster because the precharge current does not need to pass through the cascode transistor. Instead, the precharge transistor (e.g., PMOS device) more quickly pulls up the bitline voltage than existing devices. In one example, the bitline can reach the supply voltage (e.g., vp) in about 5 nanoseconds (ns). In contrast, the existing devices that precharge through the cascode transistor require about 20 ns.

In one embodiment, a memory device includes a memory array having memory cells. A bitline is coupled to at least one first memory cell. Bias circuitry includes a first transistor (e.g., P1) that couples a supply voltage (e.g., vp) to the bitline. The first transistor is configured to precharge the bitline.

Sensing circuitry includes a detector having an input (e.g., node qv) coupled to the bitline. The detector is configured to detect whether the first memory cell has reached a threshold (e.g., snapped). A current source (e.g., iref) is coupled to provide a reference current to set a voltage of the input of the detector.

The sensing circuitry also includes a second transistor (e.g., an n-channel cascode transistor) (e.g., N1) that couples the input of the detector to the bitline. The second transistor is configured to change the voltage of the detector input when the first memory cell reaches the threshold.

In one example, the memory array has chalcogenide memory cells in a three-dimensional cross-point architecture. A wordline and bitline are each biased to access at least one memory cell in the array.

Various advantages are provided by the embodiments described herein. For example, these advantages include a higher read window budget, lower power consumption, a lower supply voltage, and/or faster timing.

In one example, the precharge voltage is equal for all bitlines, and no cascode device characteristic mismatches affect the read window budget (rwb). The precharge timing is fast. The supply voltage is the same voltage that biases the bitline. For example, the supply voltage can be 2.5 V, instead of 3.2 V as in existing devices.

In one exemplary advantage, the charge that flows away due to leakage during sensing passes through the precharge transistor (e.g., P1 pass transistor) and not through the cascode transistor. So, the gate to source voltage (vgs) of the detector is zero before memory cell snapback, which avoids a false read of the memory cell (e.g., node qv remains at vp).

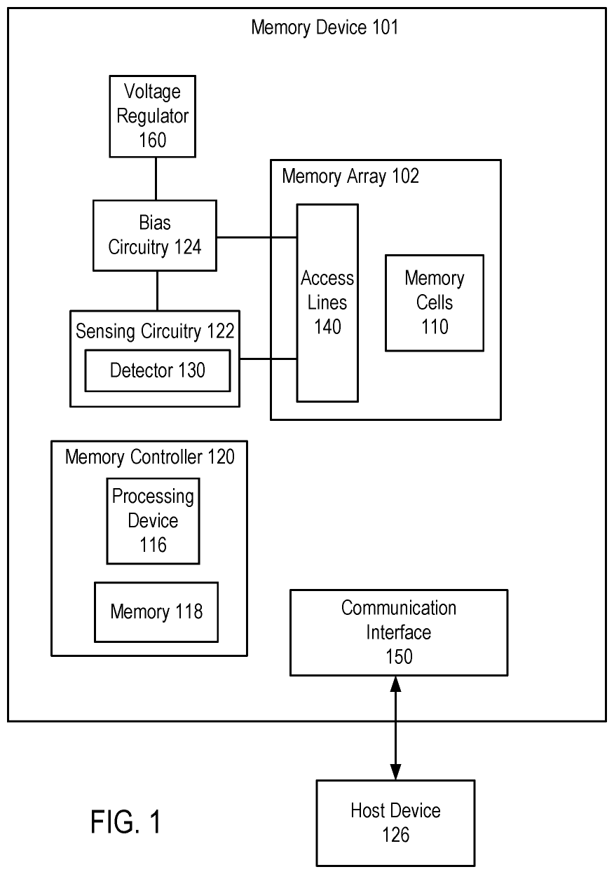

FIG. 1 shows a memory device 101 that precharges bitlines in a precharging phase in preparation for sensing memory cells 110 in a memory array 102, and turns off the precharging during sensing of the memory cells, in accordance with some embodiments. In one example, memory cells 110 are chalcogenide memory cells. In one example, controller 120 controls timing of turning on and off the precharging.

Sensing circuitry 122 senses a state of memory cells 110. Sensing circuitry 122 includes detector 130. In one example, detector 130 is a transistor, an inverter, or a differential amplifier. Memory cells 110 are selected using access lines 140. In one example, access lines 140 include wordlines and bitlines in a cross-point memory array.

Bias circuitry 124 biases selected ones of access lines 140 for selecting a portion of memory cells 110 to be sensed. Bias circuitry 124 also supplies power to sensing circuitry 122, including supplying power to detector 130.

Memory controller 120 controls various operations of memory device 101, including read and write operations on memory cells 110. Memory controller 120 includes processing device 116 and memory 118. Some operations are controlled by controller 120 in response to various commands received from host device 126 on communication interface 150.

In one embodiment, communication interface 150 receives a read command from host device 126. In response to receiving the read command, controller 120 initiates a read operation. As part of the read operation, a memory cell 110 is selected to have its logic state determined by sensing circuitry 122.

Bias circuitry 124 drives voltages on access lines 140 to select the memory cell, including driving a voltage on a bitline used to select the memory cell. To sense the state of the memory cell, detector 130 monitors a voltage on the bitline.

In one embodiment, the voltage on the bitline is first driven to an initial voltage (e.g., vp) in a precharging phase using precharging circuitry as discussed above. After the bitline reaches the initial voltage, the precharging is turned off. Then, detector 130 is used to detect whether the bitline voltage has been pulled down due to the memory cell 110 having reached a switching threshold.

Voltage regulator 160 provides one or more fixed supply voltages used by memory device 101. In one embodiment, a fixed supply voltage (e.g., vp) is provided to bias circuitry 124 for precharging a bitline connected to one of memory cells 110. The same fixed supply voltage can be used to provide power for detector 130.

It should be noted that various embodiments herein relate to precharging of bitlines in a positive supply voltage polarity. In other embodiments, the polarity can be inverted so that the circuitry uses a negative supply voltage in a similar manner as described herein for the positive supply voltage. Also, in other embodiments, a wordline or other access line may be precharged and sensed instead of, or in addition to, a bitline as discussed herein.

Detector 130 detects a change of voltage on a bitline caused by a memory cell switching (e.g., exhibiting snapback). An output of detector 130 is used by sensing circuitry 122 to determine the logic state (e.g., 1 or 0) of the memory cell that has been read.

In one embodiment, memory cells 110 store user data for host device 126. Memory cells 110 store data in either a first logic state or a second logic state. In one example, bias circuitry 124 includes wordline and bitline drivers (not shown) to bias wordlines and bitlines of memory array 102.

Sensing circuitry 122 may include sense amplifiers for sensing a characteristic associated with memory cells of the memory array 102. The characteristic can be, for example, a voltage and/or current associated with a selected memory cell.

In one embodiment, controller 120 causes bias circuitry 124 to apply voltages to selected memory cells 110. In one example, the voltages are increasing magnitudes of voltage values (e.g., +2, +2.5, +3, +3.5, +4, +4.5, +5 V) separated by steps (e.g., 0.5 V steps).

In one embodiment, memory controller 120 includes one or more processing devices 116 and memory 118. In one example, memory 118 stores firmware executed by processing device 116 to select and apply the read voltages. Memory controller 120 can use bias circuitry 124 to generate voltages for applying read and other voltages (e.g., initial read and read retry). Bias circuitry 124 can also generate voltages for applying write voltages to memory cells 110 as part of programming operations.

In one embodiment, if sensing circuitry 122 determines that the current for a memory cell is greater than a fixed threshold (e.g., a predetermined level of current), then memory controller 120 determines that the memory cell has switched (e.g., snapped).

In one embodiment, memory controller 120 receives a write command from host device 126. The write command is accompanied by data (e.g., user data of a user of host device 126) to be written to memory array 102. In response to receiving the write command, controller 120 initiates a programming operation.

In one example, the polarity of the read or write pulses may be either a first polarity or a second polarity. For example, a write pulse may apply a voltage to a memory cell in a first polarity (e.g., bitline at 6V and wordline at 0V).

In one example, circuits coupled to access lines to which memory cells may be coupled are used to provide read pulses (e.g., access line drivers included in decoder circuits). The circuits may be controlled by internal control signals provided by a control logic (e.g., controller 120). A read voltage or pulse may be a voltage applied to a memory cell for a period of time (e.g., 10-50 ns, 1-100 ns, 1 ns to 1 microsecond). In some embodiments, the read pulse may be a square pulse. In some embodiments, the read pulse may be a ramp, that is, a linearly-increasing voltage may be applied across the memory cell.

In one example, after being accessed (e.g., selected), a memory cell may be read, or sensed, by a sense component (e.g., sensing circuitry 122) to determine the stored state of the memory cell. For example, a voltage may be applied to the memory cell (using a wordline and bitline) and the presence of a resulting current may depend on the applied voltage and the threshold voltage of the memory cell. In some cases, more than one voltage may be applied. Additionally, if an applied voltage does not result in current flow, other voltages may be applied until a current is detected by the sense component.

By assessing the voltage that resulted in current flow, the stored logic state of the memory cell may be determined. In some cases, the voltage may be ramped up in magnitude until a current flow is detected (e.g., a memory cell turns on, switches on, conducts current, or becomes activated). A current may be applied to a memory cell, and the magnitude of the voltage to create the current may depend on the electrical resistance or the threshold voltage of the memory cell.

In some cases, the memory cell (e.g., a PCM cell) includes a material that changes its crystallographic configuration (e.g., between a crystalline phase and an amorphous phase), which in turn, determines a threshold voltage of the memory cell to store information. In other cases, the memory cell includes a material that remains in a crystallographic configuration (e.g., an amorphous phase) that may exhibit variable threshold voltages to store information.

The sense component may include various transistors or amplifiers in order to detect and amplify a difference in the signals. The detected logic state of the memory cell may then be output through a column decoder as output. In some cases, the sense component may be part of a column decoder or a row decoder.

At least some embodiments herein relate to memory devices that use bipolar operations for a memory array (e.g., for multi-level memory cells). In one example, bipolar select voltages are used to select memory cells of the memory array. In one example, the memory cells are arranged in a cross-point architecture. In one example, each memory cell is formed using a single select device. In one example, the select device includes a chalcogenide material that switches (e.g., snaps) when a sufficient voltage is applied across the memory cell.

In some cases, a memory device may include an array of memory cells arranged in a three-dimensional (3D) architecture, such as a cross-point architecture, to store the set of data. The memory cells in a cross-point architecture may, for example, represent a first logic state (e.g., a logic 1, a SET state) associated with a first set of threshold voltages, or a second logic state (e.g., a logic 0, a RESET state) associated with a second set of threshold voltages.

In other embodiments, the memory cells may be arranged in a three-dimensional (3D) vertical architecture. A 3D vertical architecture may include memory cells located at the crossing between a vertical access line (e.g., a bitline pillar), and each one of a plurality of second access lines (e.g., wordlines), formed in horizontal planes or decks parallel to each other.

More generally, an integrated circuit memory cell, such as a memory cell in a cross-point memory or a 3D vertical array, can be programmed to store data by the way of its state at a voltage applied across the memory cell. For example, if a memory cell is configured or programmed in such a state that allows a substantial current to pass the memory cell at a voltage in a predefined voltage region, the memory cell is considered to have been configured or programmed to store a first bit value (e.g., one or zero); and otherwise, the memory cell is storing a second bit value (e.g., zero or one).

Optionally, a memory cell can be configured or programmed to store more than one bit of data by being configured or programmed, for example, to have a threshold voltage in one of more than two separate voltage regions.

In one example, the threshold voltage of a memory cell is such that when the voltage applied across the memory cell is increased to above the threshold voltage, the memory cell switches by changing rapidly or abruptly, snapping (e.g., for a chalcogenide memory cell), or jumping from a non-conductive state to a conductive state. The non-conductive state allows a small leak current to go through the memory cell; and in contrast, the conductive state allows more than a threshold amount of current to go through. Thus, a memory device can use a detector (e.g., a sense amplifier) to detect the change, or determine the conductive/non-conductive state of the memory device at one or more applied voltages, to evaluate or classify the level of the threshold voltage of the memory cell and thus its stored data.

The threshold voltage of a memory cell being configured/programmed to be in different voltage regions can be used to represent different data values stored in the memory cell. For example, the threshold voltage of the memory cell can be programmed to be in any of four predefined voltage regions; and each of the regions can be used to represent the bit values of a different two-bit data item. Thus, when given a two-bit data item, one of the four voltage regions can be selected based on a mapping between two-bit data items and voltage regions; and the threshold voltage of the memory cell can be adjusted, programmed, or configured to be in the selected voltage region to represent or store the given two-bit data item.

To retrieve, determine, or read the data item from the memory cell, one or more read voltages can be applied across the memory cell to determine which of the four voltage regions contain the threshold voltage of the memory cell. The identification of the voltage region that contains the threshold voltage of the memory cell provides the two-bit data item that has been stored, programmed, or written into the memory cell.

For example, a memory cell can be configured or programmed to store a one-bit data item in a Single Level Cell (SLC) mode, or a two-bit data item in a Multi-Level Cell (MLC) mode, or a three-bit data item in a Triple Level Cell (TLC) mode, or a four-bit data item in Quad-Level Cell (QLC) mode.

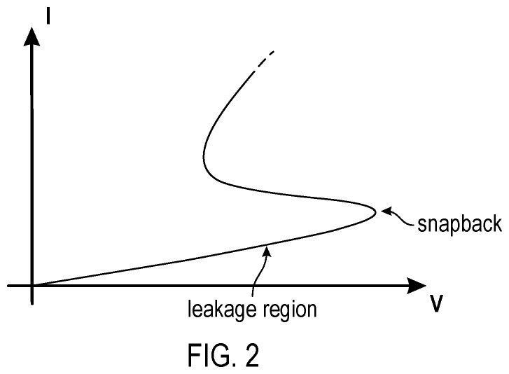

FIG. 2 shows an exemplary current-voltage (I-V) curve for a memory cell, in accordance with some embodiments. As illustrated, a current I through the memory cell monotonically increases (in a leakage region) as a voltage V applied across the memory cell increases.

The current increases with increasing voltage until the threshold voltage of the memory cell is reached. At this point, the memory cell switches and exhibits a snapback behavior as illustrated in which the current through the memory cell rapidly increases. For example, this current through the memory cell after snapback pulls down a voltage on a selected bitline so that detector 130 detects that the memory cell has reached a threshold and snapped.

As one example, the illustrated I-V curve is for a chalcogenide memory cell. Other types of phase change memory cells exhibit a similar snapback behavior. In one example, the illustrated I-V curve is for one of memory cells 110.

FIG. 3 shows circuitry having parallel precharging and sensing paths for precharging a bitline 310, then detecting a state of a memory cell 302, in accordance with some embodiments. The precharging path includes p-channel transistor P1 that couples supply voltage vp to bitline 310. The sensing path includes cascode transistor N1 that is coupled to bitline 310.

Bitline 310 is used to select memory cell 302 for sensing. Memory cell 302 is an example of memory cell 110. Wordline 312 is also connected to memory cell 302. A bias voltage is applied across memory cell 302 when sensing. The bias voltage is applied by biasing bitline 310 and wordline 312.

When precharging bitline 310, the voltage of bitline 310 is raised to the supply voltage vp by pull-up transistor P1. Transistor P1 is turned on and turned off by applying a gate voltage (the signal ignite! as illustrated).

Transistor N1 is in an off state when the bitline voltage has been precharged to vp. The gate voltage casc of transistor N1 is selected so that vp>v(casc)-vt(N1), where v(casc) is the gate voltage of transistor N1, and vt(N1) is the threshold voltage of transistor N1.

After precharging bitline 310 to voltage vp, transistor P1 is turned off to enter a sensing phase to determine a state of memory cell 302. If memory cell 302 has switched during the precharging phase, then in the sensing phase a memory cell current (e.g., cell current due to snapback) will pull down the bitline voltage sufficiently that transistor N1 turns on. Transistor N1 turns on when the voltage of bitline 310 is less than v(casc)-vt(N1).

When turned on, transistor N1 pulls down the voltage of node qv. This lowers the gate voltage of detector transistor 304 so that the voltage of evaluation node 306 is pulled up to voltage vp by transistor 304. Evaluation node 306 can be provided as an output from the detection circuitry. For example, this output can be used by controller 120 to determine the logic state of memory cell 302. In one example, transistor 304 is part of detector 130.

Current source 314 provides a reference current iref that precharges node qv and raises the voltage of node qv to supply voltage vp. In the case for which memory cell 302 does not switch, the voltage of bitline 310 remains sufficiently high so that transistor N1 does not turn on, and node qv remains at voltage vp. In this case, detector transistor 304 remains off, and evaluation node 306 does not change state (e.g., voltage of node 306 remains low) (e.g., remains at negative supply voltage VSS).

It should be noted that reference current iref can be relatively small because transistor N1 is in an off state at the end of the precharging of bitline 310, as discussed above. This permits maintaining node qv at voltage vp, so that false detections of memory cell switching are avoided.

Transistor 308 is used to reset the detection circuitry in preparation for each memory cell sensing operation. The gate voltage Reset is applied to transistor 308 for controlling resetting of the detection circuitry. For example, transistor 308 pulls down the voltage of evaluation node 306 to VSS when reset.

In one example, voltage regulator 160 provides fixed voltage vp. The n-channel cascode transistor N1 does not turn on until the bitline voltage is less than vp. Thus, precharging the bitline to vp means that transistor N1 is off. For example, if vp is equal to 2 V, and the gate voltage casc is equal to 1.5 V, then bitline 310 has to fall to 1 V for transistor N1 to turn on. The reference current iref maintains node qv at vp until transistor N1 switches on.

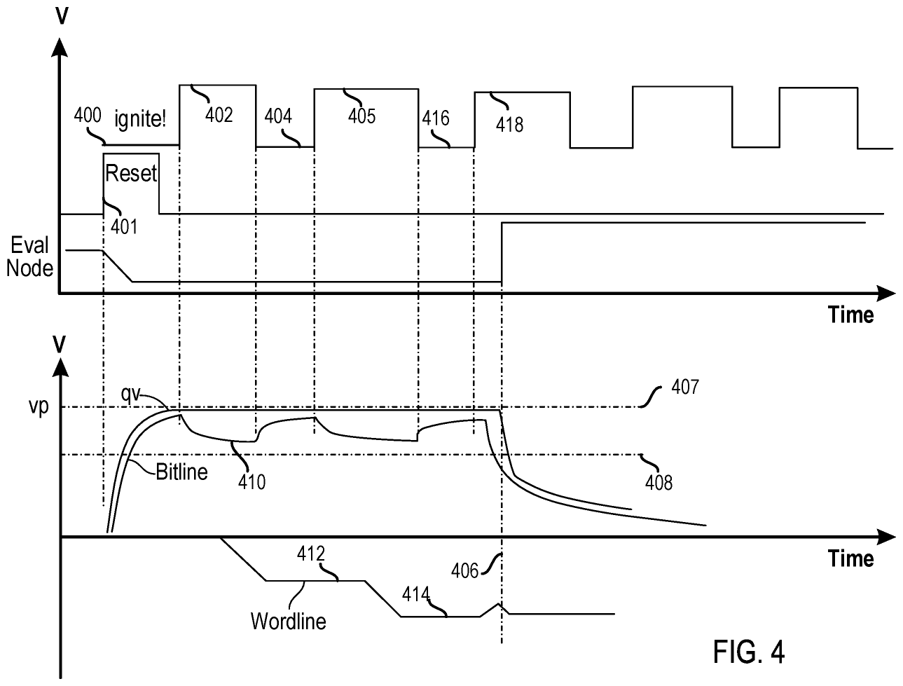

In one example, the transistor P1 is off after the memory cell 302 has switched. The bitline 310 voltage is pulled down by a significant current through memory cell 302. Transistor N1 switches on. The reference current has been selected to be 0.1 to 0.5 μA. Node qv falls, and the detector transistor 304 switches on. In contrast, if the memory cell 302 has not switched, the bitline 310 remains floating and the bitline voltage remains high (except to the extent reduced by leakage currents in the memory array; see, e.g., waveform portion 410 in FIG. 4).

In one example, bitline 302 is precharged by setting voltage ignite! low (e.g., at VSS) to turn on pass transistor P1. This avoids the problem of a slow precharge obtained through the cascode transistor N1 as in the existing devices above. The pass transistor N1 is turned off because voltage casc is chosen so that voltage vp>v(casc)-vt(N1).

The detection of snapback of memory cell 302 is made by comparing the total cell current with reference current iref. To do this, the pass transistor P1 is maintained in an on state only for a defined time interval during precharging of the bitline. In other words, transistor P1 is only used to fire (cause) the snapback of cell 302. After the time interval ends, then transistor P1 is turned off (the voltage of signal ignite! goes high).

When transistor P1 is off (e.g., disconnected), two possible cases for memory cell 302 are expected: (i) the cell has not switched, or (ii) the cell has switched.

If the cell has not switched, leakage in the memory array slowly discharges the main bitline 310. As the bitline voltage decreases, then the leakage itself will decrease and the transistor N1 remains off. Or if the bitline voltage decreases sufficiently to switch on transistor N1, then the leakage will be lower than the reference current iref. Thus, node qv is maintained high, and the detector is off.

If the cell has switched (e.g., snapback happened), the bitline voltage will see a drop and the transistor N1 switches on. The cell current will be compared with the reference current iref, and if higher, then node qv goes low and the detector will be on (a detection of cell switching occurs).

The reference current iref will flow in transistor N1 only when voltage(bitline)<v(casc)-vt(N1). There is design flexibility to choose the desired voltage level at which the reference current is compared with the cell current (icell). For example, if vp=2.5 V, v(casc) can be chosen so that v(casc)-vt(N1)=1.5 V.

For this reason, when current iref starts to flow (e.g., v(bitline)=1.5 V), the leakage will be very low as compared to the leakage of the existing devices discussed above (e.g., as measured when voltage(bitline)=vp). So, the leakage will not cause the gate voltage of detector transistor 304 to change, and this avoids false detection by the detector. Also, the precharged bitline voltage will be equal for each sense amplifier, and for this reason device characteristic mismatches for the transistors N1 among the various sense amplifiers in a memory device will not affect the various read operations.

An exemplary advantage of the above architecture is that the precharge voltage is equal for all bitlines of a memory device, and no cascode transistor N1 device characteristic mismatches affect the read window budget. The bitline voltage is decided by the regulated voltage vp of the architecture, so there are no differences between different bitlines from a biasing voltage perspective.

In an alternative embodiment, current source 314 is not needed. Node qv has a relatively low capacitance. Node qv could remain floating without the use of a reference current. In one embodiment, if desired, a small capacitor can be added to node qv.

FIG. 4 shows exemplary voltage waveforms for the circuitry of FIG. 3, in accordance with some embodiments. Voltage is indicated on the vertical axis, and time is indicated on the horizontal axis.

A sensing operation starts by resetting the detection circuitry. This is done by switching the Reset voltage high at time 401. This causes the voltage of evaluation node 306 to be pulled low in preparation for sensing memory cell 302.

Transistor P1 is turned on and off at various phases with exemplary timing as illustrated by varying the gate voltage using signal ignite !. For example, transistor P1 is turned on at phases 400, 404, 416 and turned off at phases 402, 405, 418.

At time 401, transistor P1 is turned on. As a result, the bitline voltage increases to voltage vp, as discussed above. Also, node qv is pulled up to voltage vp by reference current iref, as discussed above. As discussed above, transistor N1 is turned off towards the end of the precharging phase. The gate voltage casc selected for use in part determines the point at which the transistor N1 turns off.

After precharging is complete, transistor P1 is turned off in phase 402. As a result, due to leakage in the memory array, the bitline voltage starts to decrease at portion 410. The memory cell has not yet switched, so the evaluation node voltage remains low as the detector has not yet been triggered by the input voltage of node qv.

Transistor P1 is turned on again in phase 404. This again pulls up the voltage of the bitline to voltage vp. The magnitude of the wordline voltage is increased in a first incremental step 412.

In phase 405, transistor P1 is turned off again. However, the voltage across the memory cell is not yet sufficient to cause the memory cell to switch. Therefore, at phase 416, transistor P1 is turned on again to precharge the bitline back to voltage vp. The magnitude of the wordline voltage is increased in a next incremental step 414.

In phase 418, transistor P1 is turned off again so that the memory cell can be sensed to determine if the cell has switched. The difference between the bitline and wordline voltages applied across the memory cell was now sufficient (e.g., exceeds a threshold voltage of the memory cell) to cause the memory cell to switch. This switching of the cell is detected at node qv at time 406 by node qv being pulled down due to the significant current flowing through the switched memory cell. This causes the evaluation node 306 output to change state by going from low to high.

As a result of the memory cell switching, the voltage of the bitline is pulled below a lower voltage level 408. It is noted more generally that as the voltage of the bitline approaches higher voltage level 407, the leakage current is greater. As the voltage of the bitline approaches lower voltage level 408, the leakage current is lower. In one example, lower voltage level 408 is the gate voltage casc applied to transistor N1 minus the threshold voltage of transistor N1, which can be expressed as v(casc)-vt(N1).

In one embodiment, the gate voltage v(casc) is selected so that the leakage current at the lower voltage level 408 is negligible, and that transistor N1 does not turn on at the lower voltage level 408. Instead, transistor N1 only turns on when the memory cell switches and pulls the bitline voltage below the lower voltage level 408. The leakage current is not able to switch on the cascode transistor N1 because the leakage has become negligible as the bitline voltage has decreased. This permits using a lower reference current iref as compared to existing sense amplifiers.

Transistor N1 discharges node qv so that its voltage is pulled low when the memory cell switches. This causes detector transistor 304 to pull up the voltage of evaluation node 306 as mentioned above, which indicates that the memory cell has switched. For example, the voltage of evaluation node 306 can be provided as an output to controller 120 to indicate a logic state of the memory cell.

In one example, timing for the memory cell sensing is implemented as follows:
1. Reset of evaluation node 306 and start of bitline precharge (ignite !=0).
2. Precharge off (ignite !=1), and the leakage discharges the bitline slowly.
3. Precharge on (ignite !=0), and the wordline starts with the first incremental step.
4. Precharge off (ignite !=1).
5. Precharge on (ignite !=0), and a snapback appears; the bitline voltage drops.

When ignite !=0, an attempt is made to fire (switch) the memory cell. A magnitude of the voltage across the memory cell can be expressed as cell voltage=vp+v(wordline). The cell switches when the cell voltage is of sufficient magnitude. When ignite !=1, the voltage of node qv drops if a snapback has occurred to fire (turn on) the detector.

In one embodiment, the leakage is an exponential function of the bitline voltage. The rate of leakage decreases as the bitline voltage decreases, as illustrated (e.g., bitline waveform portion 410). Thus, below the lower voltage level 408, the leakage is negligible.

When the memory cell snaps, the bitline voltage is pulled down and the transistor N1 turns on. Node qv voltage goes down, and the detector switches on. An advantage of this architecture is that the initial voltage of node qv is equal to the bitline precharge voltage vp. This reduces power consumption compared to existing sense amplifiers.

In one embodiment, the reference current iref is not used to balance the leakage current associated with the bitline. This is because transistor N1 does not turn on until the leakage is negligible, as mentioned above. So, the reference current iref could be, for example, 0.1 microamps (μA). This compares to reference current needs of 5 to 10 μA in existing sense amplifiers.

In one embodiment, as a design choice, the reference current iref could be increased by a small amount to compensate for a tolerated low level of leakage at the lower voltage level 408. This would permit raising the lower voltage level 408 to a somewhat higher level. For example, this increase in the reference current iref might be 0.1 μA.

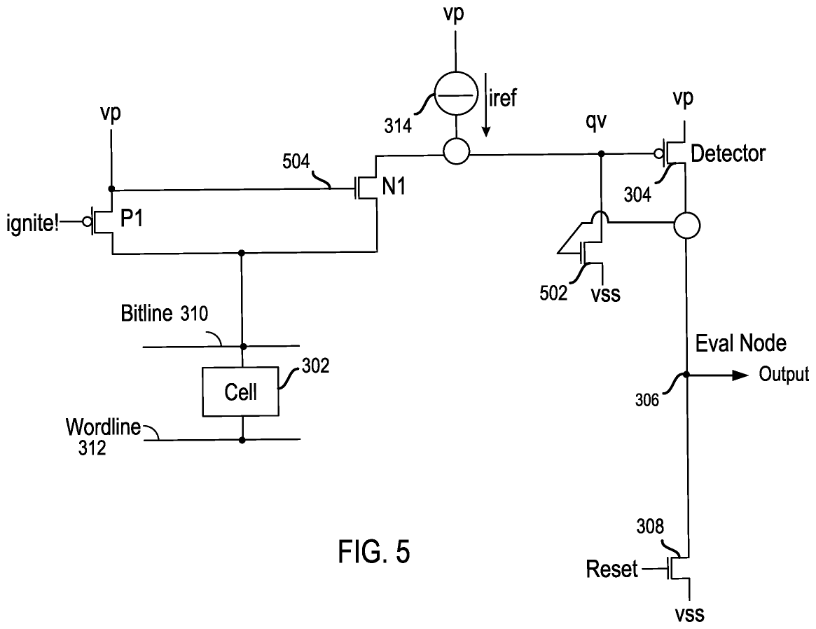

FIG. 5 shows bias circuitry coupled to a fixed voltage source (e.g., vp) for precharging a bitline, and sensing circuitry including a transistor (e.g., N1) having a gate coupled to the fixed voltage source, in accordance with some embodiments. The bias circuitry includes transistor P1, which has a current terminal coupled to fixed voltage vp.

The architecture of FIG. 5 is similar to that of FIG. 3 except that gate 504 of transistor N1 is connected to the fixed voltage source. Also, a transistor 502 has been added to latch an output value on evaluation node 306.

In one example, the fixed voltage source is a constant value vp. In one example, voltage vp is provided by voltage regulator 160.

This architecture provides an advantage by using fixed voltage vp as a gate voltage of transistor N1. This can avoid the need to create an additional voltage regulator in the periphery of a memory device chip. Also, the fixed voltage vp used to precharge the bitline is by construction higher than the bitline voltage of vp-vt(N1) needed on the bitline to switch on transistor N1, as discussed above.

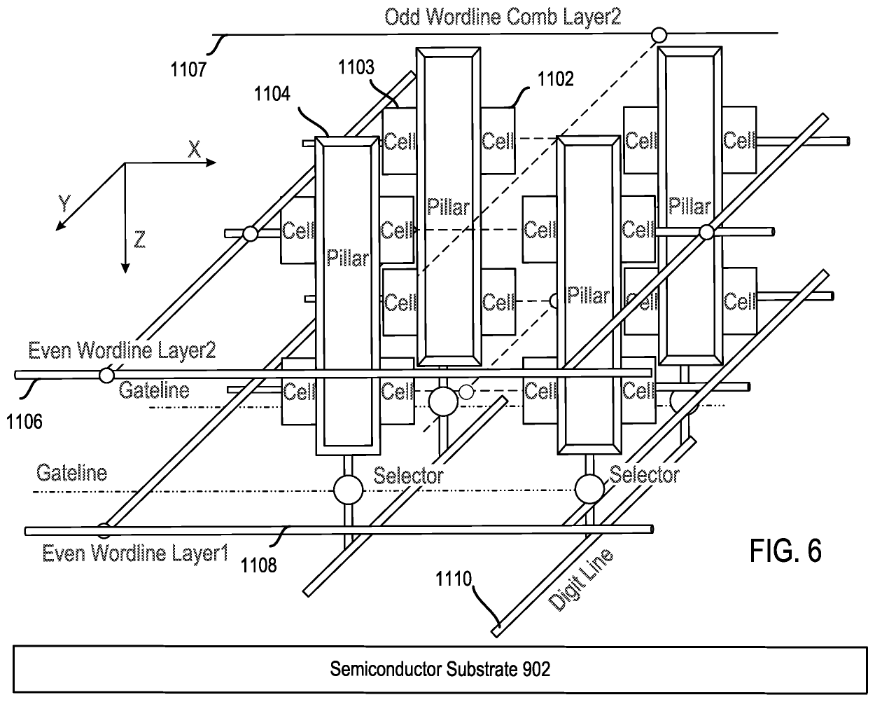

FIG. 6 shows an exemplary three-dimensional memory array structure including memory cells that are sensed by a detector, in accordance with some embodiments. In one example, the memory cells are memory cells 110 that are sensed by detector 130 of FIG. 1.

The memory array and memory cells described herein are not limited to use in a planar architecture (e.g., with cells at crossing of wordlines (WLs) and bitlines (BLs) on different levels). Instead, the approach also can be used for vertical architectures (e.g., vertical BL pillars crossing horizontal WL planes).

An example of a vertical architecture that can be used with embodiments described in this disclosure is illustrated in FIG. 6. As illustrated, a memory array includes memory cells 1102, 1103. The memory array is formed above semiconductor substrate 902. In one example, semiconductor substrate 902 includes logic circuitry. In one example, the logic circuitry provides at least a portion of bias circuitry 124 and/or sensing circuitry 122.

Each memory cell 1102, 1103 can be selected using a wordline (e.g., 1106, 1107, or 1108) and a digit line (e.g., 1110). Each digit line is coupled to a bitline pillar (e.g., 1104) by a select transistor (selector). Memory cells 1102, 1103 are an example of memory cells 110 of FIG. 1.

In one embodiment, each wordline extends in one of a plurality of horizontal planes of wordlines 1106, 1107, 1108 stacked vertically above semiconductor substrate 902. Each digit line (e.g., 1110) is coupled to a bitline pillar 1104. Each bitline pillar 1104 extends vertically away from semiconductor substrate 902. Each memory cell 1102, 1103 is located on sides of one of bitline pillars 1104.

In one embodiment, the memory array has a vertical array architecture comprising vertical bitlines (e.g., vertical pillars 1104) intersecting a plurality of horizontal decks of wordlines (e.g., even wordlines 1106 and odd wordlines 1107). Each deck is configured as two interdigitated wordline combs so that each bitline forms two cells 1102, 1103 at each of the decks. In one example, even wordlines 1106 are interdigitated with odd wordlines 1107 in a comb structure, as illustrated.

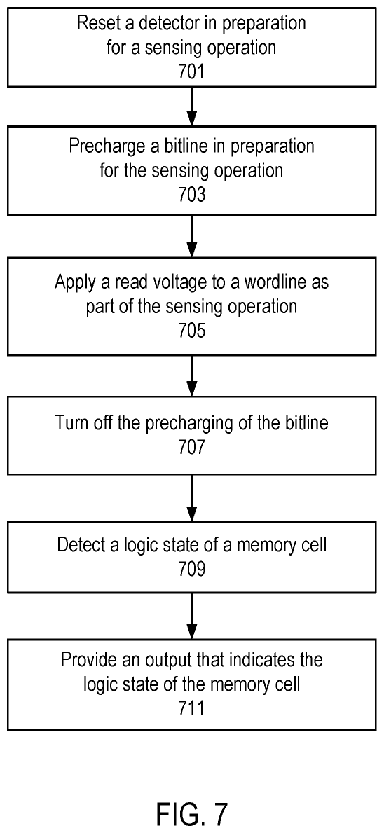

FIG. 7 shows a method for precharging a bitline prior to sensing a memory cell, in accordance with some embodiments. For example, the method of FIG. 7 can be implemented in the system of FIG. 1. In one example, the bitline is one or more of access lines 140 that is precharged by bias circuitry 124 using a fixed voltage provided by voltage regulator 160.

The method of FIG. 7 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method of FIG. 7 is performed at least in part by one or more processing devices (e.g., controller 120 of FIG. 1).

Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At block 701, a detector is reset in preparation for a sensing operation. In one example, detector 130 is reset. In one example, transistor 308 is turned on to reset evaluation node 306.

At block 703, a bitline is precharged in preparation for the sensing operation. In one example, bitline 310 is precharged to voltage vp by turning on transistor P1.

At block 705, a read voltage is applied to a wordline as part of the sensing operation. In one example, a voltage is applied to wordline 312 at step 414.

At block 707, precharging of the bitline is turned off. In one example, precharging is switched off in phase 418 by turning off transistor P1.

At block 709, the logic state of a memory cell is detected. In one example, memory cell 302 is sensed to determine whether memory cell 302 has switched. In one example, memory cell 302 switches so that the voltage of node qv is pulled down, which turns on detector transistor 304.

At block 711, an output is provided that indicates the logic state of the memory cell. In one example, detector transistor 304 turns on and raises evaluation node 306 to a high voltage state indicating detection of switching by memory cell 302. In one example, controller 120 determines a logic state of the memory cell based on sampling the voltage of evaluation node 306.

In one embodiment, an apparatus comprises: a memory array having memory cells; a bitline coupled to at least one first memory cell; a first transistor (e.g., P1) coupling a supply voltage (e.g., vp) to the bitline, wherein the first transistor is configured to precharge the bitline; a detector having an input (e.g., node qv) coupled to the bitline, wherein the detector is configured to detect whether the first memory cell has reached a threshold; a current source (e.g., iref) coupled to provide a reference current to set a voltage of the input of the detector; and a second transistor (e.g., N1) coupling the input of the detector to the bitline, wherein the second transistor is configured to change the voltage of the detector input when the first memory cell reaches the threshold.

In one embodiment, the second transistor is in an off state at an end of the first transistor precharging the bitline (e.g., transistor N1 is off when the bitline voltage has been precharged to vp).

In one embodiment, the first transistor is in an on state when precharging the bitline, and is in an off state when the detector is detecting whether the first memory cell has reached the threshold.

In one embodiment, the first transistor is a p-channel device, and the second transistor is an n-channel device.

In one embodiment, a first current terminal of the first transistor (e.g., P1 of FIG. 5) is coupled to a gate of the second transistor (e.g., N1 of FIG. 5), and a second current terminal of the first transistor is coupled to the bitline (e.g., 310).

In one embodiment, the current source (e.g., 314) is configured to drive the input of the detector to the supply voltage.

In one embodiment, the first transistor is configured to precharge the bitline to the supply voltage.

In one embodiment, a system comprises: a communication interface (e.g., 150) configured to receive a read command from a host device (e.g., 126); sensing circuitry (e.g., transistor N1 and p-channel detector) configured to sense memory cells of a memory device; bias circuitry (e.g., transistor P1) configured to bias a first access line and a second access line each coupled to at least one first memory cell, the biasing including biasing of the first access line to a first voltage in preparation for sensing the first memory cell, wherein the bias circuitry is further configured to turn off biasing of the first access line to the first voltage when sensing the first memory cell; and a controller configured to: in response to receiving the read command, initiate a read operation; bias, using the bias circuitry, the first access line (e.g., bitline) to the first voltage (e.g., vp) as part of the read operation; apply, using the bias circuitry, a voltage to the second access line (e.g., wordline) as part of the read operation; and after applying the voltage to the second access line, sense, using the sensing circuitry, the first memory cell to determine whether the first memory cell has reached a threshold.

In one embodiment, the first access line is a bitline, and the second access line is a wordline.

In one embodiment, the first access line is coupled to an input of a detector (e.g., 130) (e.g., gate of detector transistor 304), and a voltage of the input reaches a detection threshold (e.g., node qv falls below a threshold voltage of p-channel detector) in response to the first memory cell reaching the threshold.

In one embodiment, the sensing circuitry includes an n-channel transistor (e.g., cascode transistor N1), and the first access line is coupled to the input of the detector by the n-channel transistor.

In one embodiment, the system further comprises a voltage regulator (e.g., a voltage source vp) having an output to provide the first voltage, wherein the bias circuitry includes a p-channel transistor (e.g., P1), and the p-channel transistor couples the output of the voltage regulator to the first access line.

In one embodiment, the controller is further configured to: after sensing the first memory cell (which has not switched), turn on biasing (e.g., phase 404) of the first access line to the first voltage; after biasing the first access line to the first voltage, turn off biasing (e.g., phase 405) of the first access line to the first voltage; increase a magnitude of the voltage applied to the second access line (e.g., increase a step voltage on a wordline) (e.g., increase voltage to new level at step 414); and after increasing the magnitude of the voltage applied to the second access line, sense the first memory cell (e.g., sense memory cell in phase 418) while biasing of the first access line to the first voltage is turned off.

In one embodiment, the sensing circuitry (e.g., 122) includes a transistor (e.g., N1) that couples the sensing circuitry to the first access line; and the first voltage is applied to a gate of the transistor when biasing the first access line to the first voltage, and when sensing the first memory cell.

In one embodiment, a method comprises: resetting a detector (e.g., 130) in preparation for a sensing operation, wherein the detector is configured to determine a logic state of memory cells in a three-dimensional cross-point memory array formed above a semiconductor substrate, wherein a bitline of the memory array is coupled to at least one first memory cell and extends in a vertical direction above the semiconductor substrate, and wherein a wordline of the memory array is coupled to the first memory cell and extends in a horizontal direction above the semiconductor substrate;

precharging the bitline in preparation for the sensing operation; applying a read voltage to the wordline as part of the sensing operation; turning off the precharging of the bitline;

after turning off the precharging of the bitline, detecting a logic state of the first memory cell; and providing an output (e.g., evaluation node 306) indicating the logic state of the first memory cell.

In one embodiment, the first memory cell is a self-selecting memory cell, and a magnitude of a bias voltage applied across the first memory cell during the sensing operation corresponds to a threshold voltage of the first memory cell.

In one embodiment, applying the read voltage comprises incrementing the read voltage during the sensing operation by increasing a magnitude of the read voltage for each increment. In one example, the voltage on the wordline is increased at steps 412 and 414 during the sensing operation.

In one embodiment, a voltage source (e.g., regulator 160 providing constant voltage vp) is coupled to the bitline by a first transistor (e.g., P1), and precharging the bitline comprises turning on (e.g., using signal ignite!) the first transistor.

In one embodiment, a second transistor (e.g., N1) couples the bitline to an input of the detector, and the voltage source is coupled to a gate of the second transistor.

In one embodiment, a voltage of the detector input (e.g., node qv) is changed by a switching of the first memory cell, and the voltage change causes an output of the detector to change state (e.g., evaluation node 306 changes from a low voltage to a high voltage to indicate the logic state of the first memory cell).

The disclosure includes various devices which perform the methods and implement the systems described above, including data processing systems which perform these methods, and computer-readable media containing instructions which when executed on data processing systems cause the systems to perform these methods.

The description and drawings are illustrative and are not to be construed as limiting. Numerous specific details are described to provide a thorough understanding. However, in certain instances, well-known or conventional details are not described in order to avoid obscuring the description. References to one or an embodiment in the present disclosure are not necessarily references to the same embodiment; and, such references mean at least one.

As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

Reference in this specification to “one embodiment” or “an embodiment” means that a particular feature, structure, or characteristic described in connection with the embodiment is included in at least one embodiment of the disclosure. The appearances of the phrase “in one embodiment” in various places in the specification are not necessarily all referring to the same embodiment, nor are separate or alternative embodiments mutually exclusive of other embodiments. Moreover, various features are described which may be exhibited by some embodiments and not by others. Similarly, various requirements are described which may be requirements for some embodiments but not other embodiments.

In this description, various functions and/or operations may be described as being performed by or caused by software code to simplify description. However, those skilled in the art will recognize what is meant by such expressions is that the functions and/or operations result from execution of the code by one or more processing devices, such as a microprocessor, Application-Specific Integrated Circuit (ASIC), graphics processor, and/or a Field-Programmable Gate Array (FPGA). Alternatively, or in combination, the functions and operations can be implemented using special purpose circuitry (e.g., logic circuitry), with or without software instructions. Embodiments can be implemented using hardwired circuitry without software instructions, or in combination with software instructions. Thus, the techniques are not limited to any specific combination of hardware circuitry and software, nor to any particular source for the instructions executed by a computing device.

While some embodiments can be implemented in fully functioning computers and computer systems, various embodiments are capable of being distributed as a computing product in a variety of forms and are capable of being applied regardless of the particular type of computer-readable medium used to actually effect the distribution.

At least some aspects disclosed can be embodied, at least in part, in software. That is, the techniques may be carried out in a computing device or other system in response to its processing device, such as a microprocessor, executing sequences of instructions contained in a memory, such as ROM, volatile RAM, non-volatile memory, cache or a remote storage device.

Routines executed to implement the embodiments may be implemented as part of an operating system, middleware, service delivery platform, SDK (Software Development Kit) component, web services, or other specific application, component, program, object, module or sequence of instructions (sometimes referred to as computer programs). Invocation interfaces to these routines can be exposed to a software development community as an API (Application Programming Interface). The computer programs typically comprise one or more instructions set at various times in various memory and storage devices in a computer, and that, when read and executed by one or more processors in a computer, cause the computer to perform operations necessary to execute elements involving the various aspects.

A computer-readable medium can be used to store software and data which when executed by a computing device causes the device to perform various methods. The executable software and data may be stored in various places including, for example, ROM, volatile RAM, non-volatile memory and/or cache. Portions of this software and/or data may be stored in any one of these storage devices. Further, the data and instructions can be obtained from centralized servers or peer to peer networks. Different portions of the data and instructions can be obtained from different centralized servers and/or peer to peer networks at different times and in different communication sessions or in a same communication session. The data and instructions can be obtained in entirety prior to the execution of the applications. Alternatively, portions of the data and instructions can be obtained dynamically, just in time, when needed for execution. Thus, it is not required that the data and instructions be on a computer-readable medium in entirety at a particular instance of time.

Examples of computer-readable media include, but are not limited to, recordable and non-recordable type media such as volatile and non-volatile memory devices, read only memory (ROM), random access memory (RAM), flash memory devices, solid-state drive storage media, removable disks, magnetic disk storage media, optical storage media (e.g., Compact Disk Read-Only Memory (CD ROMs), Digital Versatile Disks (DVDs), etc.), among others. The computer-readable media may store the instructions. Other examples of computer-readable media include, but are not limited to, non-volatile embedded devices using NOR flash or NAND flash architectures. Media used in these architectures may include un-managed NAND devices and/or managed NAND devices, including, for example, eMMC, SD, CF, UFS, and SSD.

In general, a non-transitory computer-readable medium includes any mechanism that provides (e.g., stores) information in a form accessible by a computing device (e.g., a computer, mobile device, network device, personal digital assistant, manufacturing tool having a controller, any device with a set of one or more processors, etc.). A “computer-readable medium” as used herein may include a single medium or multiple media (e.g., that store one or more sets of instructions).

In various embodiments, hardwired circuitry may be used in combination with software and firmware instructions to implement the techniques. Thus, the techniques are neither limited to any specific combination of hardware circuitry and software nor to any particular source for the instructions executed by a computing device.

Various embodiments set forth herein can be implemented using a wide variety of different types of computing devices. As used herein, examples of a “computing device” include, but are not limited to, a server, a centralized computing platform, a system of multiple computing processors and/or components, a mobile device, a user terminal, a vehicle, a personal communications device, a wearable digital device, an electronic kiosk, a general purpose computer, an electronic document reader, a tablet, a laptop computer, a smartphone, a digital camera, a residential domestic appliance, a television, or a digital music player. Additional examples of computing devices include devices that are part of what is called “the internet of things” (IOT). Such “things” may have occasional interactions with their owners or administrators, who may monitor the things or modify settings on these things. In some cases, such owners or administrators play the role of users with respect to the “thing” devices. In some examples, the primary mobile device (e.g., an Apple iPhone) of a user may be an administrator server with respect to a paired “thing” device that is worn by the user (e.g., an Apple watch).

In some embodiments, the computing device can be a computer or host system, which is implemented, for example, as a desktop computer, laptop computer, network server, mobile device, or other computing device that includes a memory and a processing device. The host system can include or be coupled to a memory sub-system so that the host system can read data from or write data to the memory sub-system. The host system can be coupled to the memory sub-system via a physical host interface. In general, the host system can access multiple memory sub-systems via a same communication connection, multiple separate communication connections, and/or a combination of communication connections.

In some embodiments, the computing device is a system including one or more processing devices. Examples of the processing device can include a microcontroller, a central processing unit (CPU), special purpose logic circuitry (e.g., a field programmable gate array (FPGA), an application specific integrated circuit (ASIC), etc.), a system on a chip (SoC), or another suitable processor.

In one example, a computing device is a controller of a memory system. The controller includes a processing device and memory containing instructions executed by the processing device to control various operations of the memory system.

Although some of the drawings illustrate a number of operations in a particular order, operations which are not order dependent may be reordered and other operations may be combined or broken out. While some reordering or other groupings are specifically mentioned, others will be apparent to those of ordinary skill in the art and so do not present an exhaustive list of alternatives. Moreover, it should be recognized that the stages could be implemented in hardware, firmware, software or any combination thereof.

Disjunctive language such as the phrase “at least one of X, Y, or Z,” unless specifically stated otherwise, is otherwise understood with the context as used in general to present that an item, term, etc., may be either X, Y, or Z, or any combination thereof (e.g., X, Y, and/or Z). Thus, such disjunctive language is not generally intended to, and should not, imply that certain embodiments require at least one of X, at least one of Y, or at least one of Z to each be present.

In the foregoing specification, the disclosure has been described with reference to specific exemplary embodiments thereof. It will be evident that various modifications may be made thereto without departing from the broader spirit and scope as set forth in the following claims. The specification and drawings are, accordingly, to be regarded in an illustrative sense rather than a restrictive sense.

What is claimed is:

1. An apparatus comprising:
a memory array having memory cells;
a bitline coupled to at least one first memory cell;
a first transistor coupling a supply voltage to the bitline, wherein the first transistor is configured to precharge the bitline;
a detector having an input coupled to the bitline, wherein the detector is configured to detect whether the first memory cell has reached a threshold;
a current source coupled to provide a reference current to set a voltage of the input of the detector; and
a second transistor coupling the input of the detector to the bitline, wherein the second transistor is configured to change the voltage of the detector input when the first memory cell reaches the threshold.

2. The apparatus of claim 1, wherein the second transistor is in an off state at an end of the first transistor precharging the bitline.

3. The apparatus of claim 1, wherein the first transistor is in an on state when precharging the bitline, and is in an off state when the detector is detecting whether the first memory cell has reached the threshold.

4. The apparatus of claim 1, wherein the first transistor is a p-channel device, and the second transistor is an n-channel device.

5. The apparatus of claim 1, wherein a first current terminal of the first transistor is coupled to a gate of the second transistor, and a second current terminal of the first transistor is coupled to the bitline.

6. The apparatus of claim 1, wherein the current source is configured to drive the input of the detector to the supply voltage.

7. The apparatus of claim 1, wherein the first transistor is configured to precharge the bitline to the supply voltage.

8. A system comprising:
a communication interface configured to receive a read command from a host device;
sensing circuitry configured to sense memory cells of a memory device;
bias circuitry configured to bias a first access line and a second access line each coupled to at least one first memory cell, the biasing including biasing of the first access line to a first voltage in preparation for sensing the first memory cell, wherein the bias circuitry is further configured to turn off biasing of the first access line to the first voltage when sensing the first memory cell; and
a controller configured to:
in response to receiving the read command, initiate a read operation;
bias, using the bias circuitry, the first access line to the first voltage as part of the read operation;
apply, using the bias circuitry, a voltage to the second access line as part of the read operation; and
after applying the voltage to the second access line, sense, using the sensing circuitry, the first memory cell to determine whether the first memory cell has reached a threshold.

9. The system of claim 8, wherein the first access line is a bitline, and the second access line is a wordline.

10. The system of claim 8, wherein the first access line is coupled to an input of a detector, and a voltage of the input reaches a detection threshold in response to the first memory cell reaching the threshold.

11. The system of claim 10, wherein the sensing circuitry includes an n-channel transistor, and the first access line is coupled to the input of the detector by the n-channel transistor.

12. The system of claim 8, further comprising a voltage regulator having an output to provide the first voltage, wherein the bias circuitry includes a p-channel transistor, and the p-channel transistor couples the output of the voltage regulator to the first access line.

13. The system of claim 8, wherein the controller is further configured to:
after sensing the first memory cell, turn on biasing of the first access line to the first voltage;
after biasing the first access line to the first voltage, turn off biasing of the first access line to the first voltage;
increase a magnitude of the voltage applied to the second access line; and
after increasing the magnitude of the voltage applied to the second access line, sense the first memory cell while biasing of the first access line to the first voltage is turned off.

14. The system of claim 8, wherein:
the sensing circuitry includes a transistor that couples the sensing circuitry to the first access line; and
the first voltage is applied to a gate of the transistor when biasing the first access line to the first voltage, and when sensing the first memory cell.

15. A method comprising:
resetting a detector in preparation for a sensing operation, wherein the detector is configured to determine a logic state of memory cells in a three-dimensional cross-point memory array formed above a semiconductor substrate, wherein a bitline of the memory array is coupled to at least one first memory cell and extends in a vertical direction above the semiconductor substrate, and wherein a wordline of the memory array is coupled to the first memory cell and extends in a horizontal direction above the semiconductor substrate;
precharging the bitline in preparation for the sensing operation;
applying a read voltage to the wordline as part of the sensing operation;
turning off the precharging of the bitline;
after turning off the precharging of the bitline, detecting a logic state of the first memory cell; and
providing an output indicating the logic state of the first memory cell.

16. The method of claim 15, wherein the first memory cell is a self-selecting memory cell, and a magnitude of a bias voltage applied across the first memory cell during the sensing operation corresponds to a threshold voltage of the first memory cell.

17. The method of claim 15, wherein applying the read voltage comprises incrementing the read voltage during the sensing operation by increasing a magnitude of the read voltage for each increment.

18. The method of claim 15, wherein a voltage source is coupled to the bitline by a first transistor, and precharging the bitline comprises turning on the first transistor.

19. The method of claim 18, wherein a second transistor couples the bitline to an input of the detector, and the voltage source is coupled to a gate of the second transistor.

20. The method of claim 19, wherein a voltage of the detector input is changed by a switching of the first memory cell, and the voltage change causes an output of the detector to change state.
